(19) United States
(12) Patent Application Publication
(10) Pub. No.: US 2013/0128106 A1
(43) Pub. Date: May 23, 2013

(54) CAMERA MODULE HOUSING HAVING MOLDED TAPE SUBSTRATE WITH FOLDED LEADS

(71) Applicants: Samuel Tam, Daly City, CA (US); Harpuneet Singh, Dublin, CA (US)

(72) Inventors: Samuel Tam, Daly City, CA (US); Harpuneet Singh, Dublin, CA (US)

(73) Assignee: Flextronics AP, LLC, Broomfield, CO (US)

(21) Appl. No.: 13/303,312

(22) Filed: Nov. 23, 2011

(51) Int. Cl. H04N 5/225; H05K 13/00

(52) U.S. Cl. 348/374; 29/592.1

(57) ABSTRACT

A camera module including a flexible tape substrate (e.g., a flexible printed circuit tape portion) having a plurality of surface mount components and a first frame member mounted to a first side of the substrate and an image sensor and a frame member mounted to an opposing second side of the substrate. The substrate includes a body portion and one or more leads or wing members having conductive contacts thereon extending from the body portion. The wing members may be folded onto the second frame member so that the conductive contacts of the wing members generally face in a different direction than conductive contacts of the body portion to provide an electrical path to the surface mount components in a manner that is free of using vias extending through the substrate. A tubular housing and lens barrel may be mounted to the substrate over the first frame member.

### BACKGROUND

Digital camera technology is being used in an increasing variety of mass-produced applications. A growing use of digital camera technology is incorporating or providing fixed-focus camera modules in consumer products such as wireless telephones, cell phones, personal digital assistants (PDAs), and other handheld electronic devices. While many consumers demand high-end functionality and quality, many consumers want the functions such as those provided by a digital camera but at affordable prices. For instance, it is estimated that that more than 65 percent of cell phones will include cameras. Additionally, there are many companies that produce consumer products such as cell phones and PDAs, and this competition requires that components including camera modules be produced with high quality but at acceptable costs with lower per unit material and assembly costs. This is especially true for products in which the camera is a secondary component such as when the product is primarily a communication device.

Fixed-focus camera modules used in many consumer products generally include a lens for focusing incoming light onto an image sensor that detects an image and converts it into an electrical signal representation. An image processor manipulates the image signal into an image that is stored or displayed on a display screen. Camera modules also include a chassis and enclosure for mounting the various electronic and optical components and for protecting the components from particulate and spurious light contamination.

Turning to FIG. 1, a conventional camera module 10 is illustrated that may be used to provide digital imaging functionality in a consumer product or application such as a wireless or cellular phone, tablet computer, and the like. As shown, the module 10 includes a housing 22 (e.g., constructed of thermoplastic polymer such as polyvinyl chloride or PVC) having an internal cavity 24 with a first portion 26 that is adapted to receive a corresponding portion of a lens barrel 14 having at least one lens element 18 (via respective threaded portions 30, 34 on the housing 22 and lens barrel 14) and a second portion 38 that is adapted to receive and/or interconnect with a number of dies and other components that are generally collectively operable to receive and process incoming light passing through the lens element 18 to store and/or display a corresponding image. An infrared (IR) filter 90 for filtering longer-wavelength radiation to limit noise created in an image sensor 58 is disposed within the internal cavity. A transparent lens cover 19 is disposed within or over an aperture 20 in the lens barrel 14 to allow the lens element 18 to receive light while protecting the lens element 18 and other components of the module 10 from particulates and other debris.

The module 10 includes a PCBA 42 (e.g., a multi-layer ceramic substrate) having first and second opposing surfaces 46, 50 for receiving one or more components and dies. An image sensor 52 including a first die 54 and an imaging chip 58 (e.g., CMOS chip) is electrically interconnected to the PCBA 42 by way of laying the first die 54 over the first surface 46 and bonding both ends of one or more pairs of wires 62 (e.g., gold) to respective contact pads 66, 70 on the first die 54 and the first surface 46 of the PCBA 42. Before the image sensor 52 is laid over the first surface 46, an underfill such as a non-conductive paste (NCP) 72 is disposed on at least one of the first surface 46 and the first die 54 to further secure the first die 54 to the first surface 46 upon laying of the first die 54 over the first surface 46.

A second die 74 (e.g., a JPEG or graphics chip) is electrically interconnected to the second surface 50 of the PCBA 42 by way of a flip chip connection. More specifically, the second die 74 includes at least a pair of stud or solder bumps 78 that are spaced to align with a corresponding spaced pair of contact pads 82 on the second surface 50 of the PCBA 42. Upon flipping the second die 74 upside down and aligning the solder bumps 78 with the contact pads 82, flowing of the solder bumps 78 completes the electrical interconnect between the second die 74 and the PCBA 42. Again, before the second die 74 is disposed against the second surface 50, NCP 73 is disposed on at least one of the second surface 50 and the second die 74 to further secure the second die 74 to the second surface 50 when the second die 74 is disposed against the second surface 50. Furthermore, one or more surface mount technology (SMT) passive components 84 are electrically interconnected to the second surface 50 of the PCBA 42 via respective contact pads 86.

To assemble the module 10, the PCBA 42 is arranged so that the first die 54 is inserted into or otherwise disposed in the second portion 38 of the internal cavity 24 and faces the lens element 18 and an epoxy 88 is used to connect the PCBA 42 (e.g., via the first surface 46) to the housing 22. Also, the lens barrel 14 is threaded into the first portion 26 to a position whereby the lens element 18 accurately focuses incoming light onto the imaging chip 58. As shown, the lens element 18, IR filter 90, imaging chip 58, first die 54, PCBA 42 and second die 74 are generally arranged so that their centers (not labeled) lie along an axis 92. The module 10 may be incorporated into a consumer product and appropriately interconnected to the system controller or processing unit of the product.

Camera modules such as the camera module 10 discussed above suffer from a number of drawbacks. In one regard, the eight or more layers (e.g., metal foils, bonding films and the like) typically needed to assembly the PCBA 42 results in high substrate costs, increased camera module thickness, and increased warpage; increased warpage leads to the need for a pair of gold stud bumps (e.g., instead of a single gold stud bump) and the inability to use a gang bonding head leading to an overall reduction in throughput. Furthermore, use of a substrate made up of an increased number of layers requires use of a snapping or dicing process instead of a simpler punching process, for instance. Still further, electrically connecting the SMT passive components 84 to the PCBA 42 typically involves the use of vias which can reduce the structural and electrical integrity of the PCBA 42.

### SUMMARY

Disclosed herein is a method for use in building a camera module for use in electronic devices including providing a flexible printed circuit tape portion including a body portion having opposing first and second surfaces and a plurality of conductive contacts disposed on the first and second surfaces, a central opening disposed through the body portion, and at least one wing member extending from the body portion and including a plurality of conductive contacts, where the conductive contacts of the body portion are electrically interconnected to the conductive contacts of the at least one wing member. The method also includes mounting a frame member to the second surface of the body portion about the central opening, electrically interconnecting an image sensor to the conductive contacts on the second surface of the body portion and over the central opening, and folding the at least one wing member onto the frame member so that the conductive contacts of the wing member generally face in a direction that is different from a direction in which the conductive contacts on the first surface of the body portion face.

After the folding, the conductive contacts of the at least one wing member may generally face in a direction that is spaced by about 180° from the direction in which the conductive contacts on the first surface of the body portion face and/or at least a portion of the at least one wing member resides in a plane that is generally parallel to a plane in which the body portion resides.

The at least one wing member may be secured to the frame member. The at least one wing member may include a first wing member, the flexible printed circuit tape portion may further include a second wing member spaced from the first wing member, and the method may further include folding the second wing member onto the frame member so that the conductive contacts of the second wing member generally face in a direction that is different from the direction in which the conductive contacts on the first surface of the body portion face. The flexible printed circuit tape portion may further include a third wing member disposed between the first and second wing members, and the method may further include folding the third wing member onto the frame member so that the conductive contacts of the third wing member generally face in a direction that is different from the direction in which the conductive contacts on the first surface of the body portion face.

The method may include electrically mounting a plurality of surface mount components to the conductive contacts on the first surface of the body portion. The frame member mounted to the second surface of the body portion may be a second frame member, and the method may further include mounting a first frame member to the first surface of the body portion and over the surface mount components. The first frame member may include opposing first and second surfaces and an opening extending between the first and second surfaces, and the method may further include inserting an infrared (IR) filter into the first frame member opening and securing the IR filter to the first surface of the body portion. The method may further include mounting a housing to the first surface of the body portion, where the housing includes a tubular body having opposing first and second ends and an internal cavity between the first and second ends that is generally aligned with the central opening. The folding may occur after the first frame member and housing are mounted to the body portion. A lens barrel including at least one lens element may be inserted into the internal cavity.

The flexible printed circuit tape portion may be provided on a length of flexible tape substrate along with a plurality of other flexible printed circuit tape portions, and the method may include separating (e.g., punching) the flexible printed circuit tape portion from the length of flexible tape substrate. The image sensor may be electrically interconnected to the body portion before the frame member is mounted to the body portion. The frame member may include opposing first and second surfaces and a cavity extending from one of the first and second surfaces towards but short of the other of the first and second surfaces, and the mounting may include mounting the cavity over the image sensor. The image sensor may be electrically interconnected to the body portion after the frame member has been mounted to the body portion. The frame member may include opposing first and second surfaces and an opening extending between the first and second surfaces, and the electrically interconnecting the image sensor may include inserting the image sensor into the frame member opening. The electrically interconnecting the image sensor may involve performing a flip chip bonding process between the image sensor and the conductive contacts of the body portion.

Also disclosed herein is an apparatus including a flexible tape substrate having a body portion having opposing first and second surfaces and a plurality of conductive contacts disposed on the first and second surfaces, a central opening disposed through the body portion, and at least one wing member extending from the body portion and including a plurality of conductive contacts, where the conductive contacts of the body portion are electrically interconnected to the conductive contacts of the at least one wing member. The apparatus also includes a frame member mounted to the second surface of the body portion about the central opening, and an image sensor electrically interconnected to the conductive contacts on the second surface of the body portion and over the central opening. The at least one wing member is secured to the frame member so that the conductive contacts of the at least one wing member generally face in a direction that is different from a direction in which the conductive contacts on the first surface of the body portion face.

The frame member may include a first surface secured to the second surface of the body portion, an opposing second surface, and an opening extending between the first and second surfaces where the image sensor is disposed within the frame member opening. The frame member may include a thickness extending from the first surface to the second surface and the image sensor may have a thickness extending from a first surface of the image sensor to a second surface of the image sensor whereby the frame member thickness may be substantially equal to or greater than the image sensor thickness. The frame member opening may extend from the first surface of the frame member towards but short of the second surface of the frame member. The frame member may include a thermally conductive material.

The frame member may be a second frame member, and the apparatus may further include a plurality of surface mount components electrically interconnected to the conductive contacts on the first surface of the body portion and a first frame member mounted to the first surface of the body portion and over the surface mount components. The first frame member may include opposing first and second surfaces and an opening extending between the first and second surfaces, and the apparatus may further include an infrared (IR) filter disposed within the first frame member opening and secured to the first surface of the body portion. The apparatus may also include a housing mounted to the first surface of the body portion and over the first frame member. The housing may have a tubular body having opposing first and second ends and an internal cavity between the first and second ends that is generally aligned with the central opening. There may be a lens barrel including at least one lens element disposed within the internal cavity. The first frame member may include a polymer.

The at least one wing member may include a first wing member, the flexible tape substrate may include a second wing member spaced from the first wing member, and the second wing member may be secured to the frame member so that the conductive contacts of the second wing member generally face in a direction that is different from the direction in which the conductive contacts on the first surface of the body portion face. The flexible tape substrate may further include a third wing member disposed between the first and second wing members and secured to the frame member so that the conductive contacts of the third wing member generally face in a direction that is different from the direction in which the conductive contacts on the first surface of the body portion face.

### BRIEF DESCRIPTION OF THE DRAWINGS

FIG. 1 is a side view of a camera module assembly according to the prior art.

FIG. 2 is a flow diagram illustrating a method of fabricating a camera module.

FIGS. 3-13b illustrate various steps in the method of FIG. 2.

FIG. 14 is a cross-sectional view of a camera module fabricated by the method of FIG. 2 according to one embodiment.

FIG. 15 is a cross-sectional view of a camera module fabricated by the method of FIG. 2 according to another embodiment.

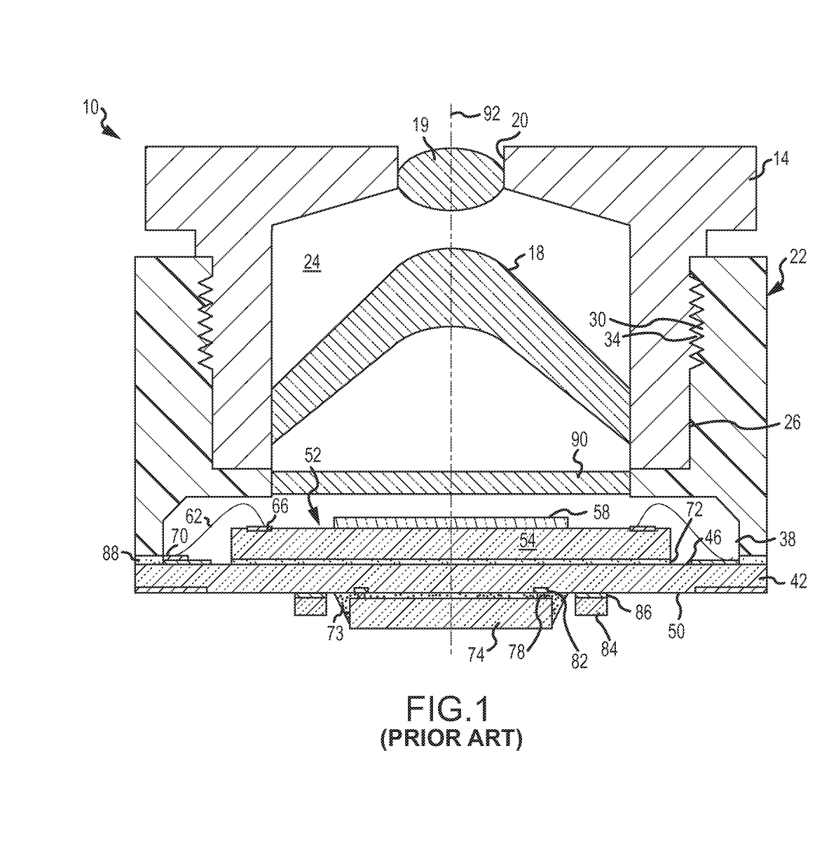

### DETAILED DESCRIPTION

While the invention is susceptible to various modifications and alternative forms, specific embodiments thereof have been shown by way of example in the drawings and are herein described in detail. It should be understood, however, that it is not intended to limit the invention to the particular form disclosed, but rather, the invention is to cover all modifications, equivalents, and alternatives falling within the scope and spirit of the invention as defined by the claims.

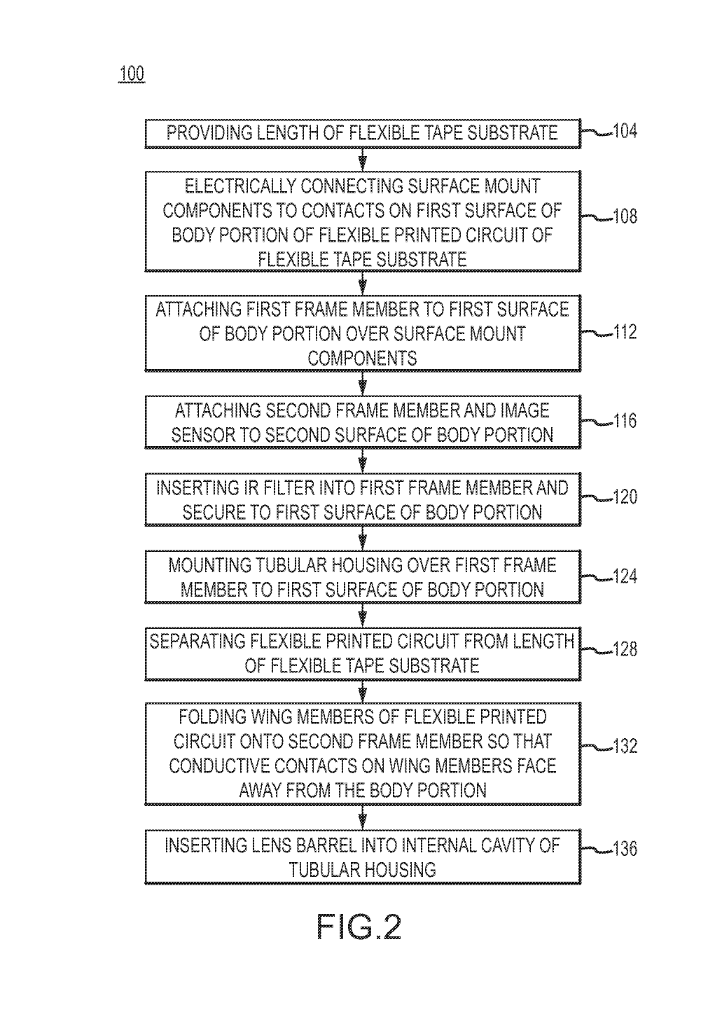

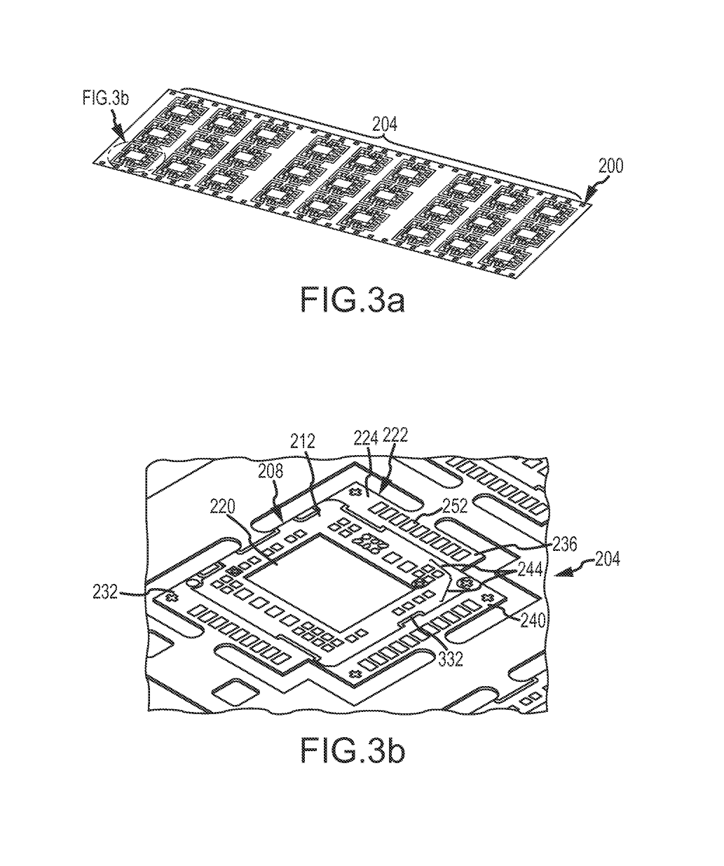

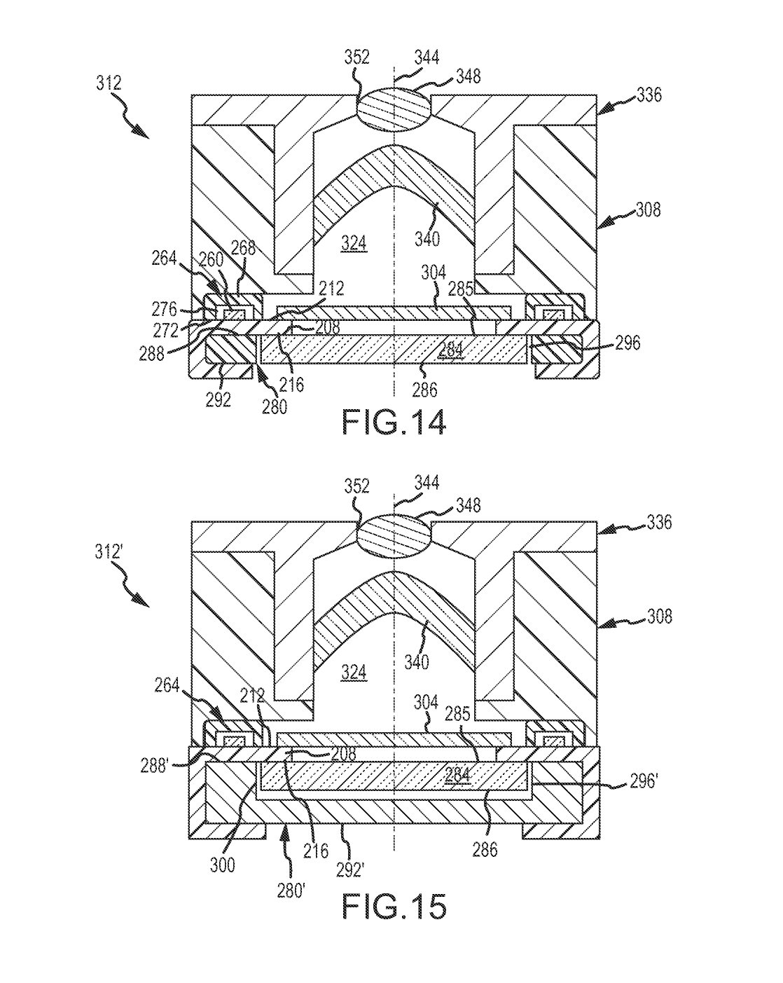

FIG. 2 presents a flow diagram illustrating a method 100 for fabricating a camera module according to the teachings presented herein. In conjunction with a discussion of the method 100 of FIG. 2, reference will also be made to FIGS. 3-13b which illustrate various intermediate steps of the method 100 as well as FIGS. 14-15 which illustrate cross-sectional views of camera modules 312/312′ fabricated by the method 100. Unless otherwise specified, the figures may not necessarily be drawn to scale. As will be disclosed in the following discussion, the method 100 makes use of the inherent flexibility of a flexible printed circuit tape substrate or portion to avoid or at least limit the use of vias that would otherwise extend through the substrate to electrically interconnect components on or adjacent first and second surfaces of the substrate by way of folding flexible and electrically conductive leads or wing members of the substrate onto a frame member and then electrically connecting conductive pads of the wing members onto a circuit board or other component of an electronic device (e.g., consumer product such as a camera, smart phone, etc.).

The method 100 may include providing 104 a length of flexible tape substrate 200 including a plurality of flexible printed circuit tape portions or flexible printed circuits 204 formed therein or thereon (see FIG. 3a). For instance, the flexible tape substrate 200 may be a high density interconnect (HDI) tape substrate made up of any appropriate number (e.g., 2-4) of alternating layers of conductive and non-conductive material (e.g. copper layers, polyimide layers, etc.) and manufactured in a manner (e.g., including etching and the like) that creates the plurality of flexible printed circuits 204, each having an network of conductive traces, contacts, and the like. While not shown, the flexible tape substrate 200 may be stored on any appropriate reel and unwound to begin the fabrication method 100.

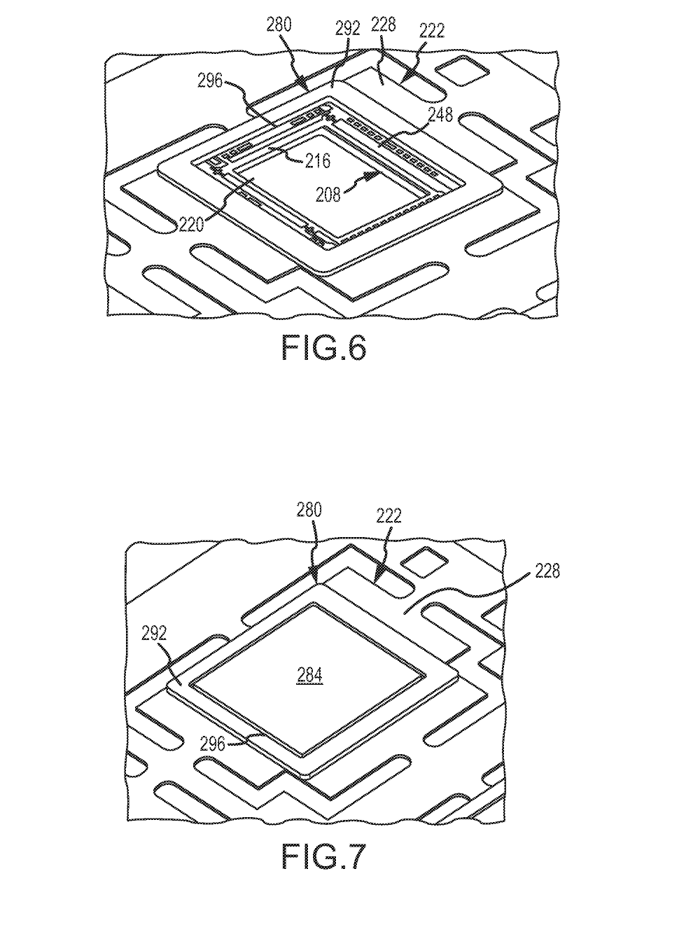

Turning now to FIG. 3b, a close-up perspective view of a flexible printed circuit 204 is shown. The flexible printed circuit 204 broadly includes a body portion 208 having a first surface 212 and an opposing second surface 216 (see FIG. 6), a central opening 220 extending through the body portion 208 between the first and second surfaces 212, 216, and one or more lead or wing members 222 (such as first, second and third wing members 232, 236, 240) extending from the body portion 208 and having a first surface 224 and an opposing second surface 228 (see FIG. 6). Each of the first and second surfaces 212, 216 of the body portion 208 may include a number of conductive pads or contacts 244, 248 that are appropriately electrically interconnected to a plurality of conductive pads or contacts 252 disposed on the first surface 224 of the wing members 222 by way of a number of conductive traces (not labeled). In one arrangement and as shown, the first and second wing members 232, 236 may be spaced about the central opening 220 by about 180° and the third wing member 240 may be disposed between the first and second wing members 232, 236 and spaced from the first and second wing members 232, 236 by about 90°. Other numbers and orientations of wing members 222 are also envisioned and encompassed within the scope of the present disclosure.

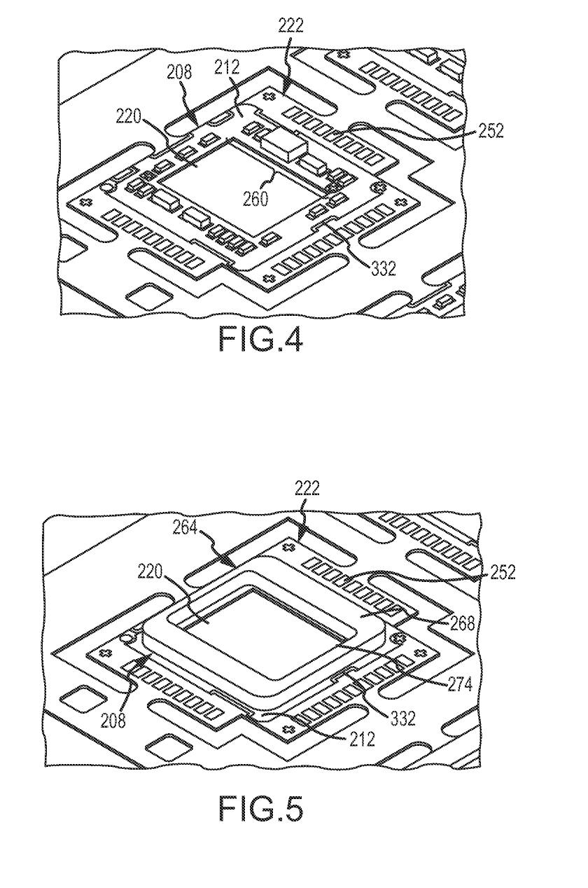

Turning back to FIG. 2, the method 100 may include electrically connecting 108 a plurality of surface mount components 260 (e.g., SMT passives such as capacitors, resistors, etc.) in any appropriate manner to the conductive contacts 244 on the first surface 212 of the body portion 208 (see FIG. 4) and attaching a first frame member 264 to the first surface 212 of the body portion 208 and over the surface mount components 260 (see FIG. 5). As shown in FIG. 5, the first frame member 264 may generally include a first surface 268, an opposing second surface 272 (see completed camera module 312 in FIG. 14) adapted to be secured to the first surface 212 of the body portion 208 in any appropriate manner (e.g., adhesives), and an opening 274 extending between the first and second surfaces 268, 272 that is operable to generally align with the central opening 220 of the body portion 208. For instance, the first frame member 264 may include a channel 276 (see FIG. 14) extending from the second surface 272 and towards the first surface 268 that is sized to receive the surface mount components 260. In this regard, mounting of the first frame member 264 to the first surface 212 of the body portion 208 and over the surface mount components 260 serves to reduce contamination of the surface mount components 260 and thereby increase reliability and handling of the surface mount components 260. Furthermore, concealing the surface mount components 260 by the first frame member 264 serves to protect the surface mount components 260 from increased temperatures that may occur during other steps of the fabrication method 100 (e.g., during bonding of an image sensor to the body portion 208, discussed below). In one arrangement, the first frame member 264 may be made of any appropriate polymer and manufactured via a transfer molding process.

The method 100 illustrated in FIG. 2 may also include attaching 116 a second frame member 280 and an image sensor 284 (e.g., CMOS die, chip or wafer) to the second surface 216 of the body portion 208. See FIGS. 6 and 7. As shown, the second frame member 280 may generally include a first surface 288 (see FIG. 14) adapted to be secured to the second surface 216 of the body portion 208 in any appropriate manner (e.g., adhesives), an opposing second surface 292 (also see FIG. 6), and an opening 296 extending between the first and second surfaces 288, 292 that is operable to generally align with the central opening 220 of the body portion 208 and the first frame member opening 274. In one arrangement, the second frame member 280 may be made of any appropriate polymer and manufactured via a transfer molding process. In another arrangement, the second frame member 280 may be made of any appropriate stiffening material (e.g., plastic, steel) that serves to increase the rigidity and otherwise enhance the structural integrity of the yet to be completed camera module.

In any event, the image sensor 284 may be inserted into the second frame member opening 296 and appropriately electrically interconnected to the conductive contacts 248 on the second surface 216 of the body portion 208 (e.g., using a flip chip process). See FIG. 7. For instance, one or more gold sputter-plated bumps (not shown) may be applied to a surface of the image sensor 284 such that when the image sensor 284 is inserted into the second frame member opening 296, the plated bumps appropriately align with corresponding conductive contacts 248 on the second surface 216 of the body portion 208. Thereafter, a thermo-compression bonding process (e.g., gang bonding) may be utilized to heat, compress and flow the plated bumps between the image sensor 284 and conductive contacts 248 to electrically interconnect the image sensor 284 to the flexible printed circuit 204.

Furthermore, constructing the second frame member opening 296 to have dimensions that are similar to those of the image sensor 284 may serve to protect the image sensor 284 from inadvertent impacts or other damage. For instance, the second frame member 280 may have a thickness extending between the first and second surfaces 288, 292 that is the same as or slightly larger than a thickness of the image sensor 284 extending between first and second opposing surfaces 285, 286 of the image sensor 284 (see FIG. 14). Furthermore, the width/length dimensions (not labeled) of the second frame member opening 296 may be about the same or slightly larger than those (not labeled) of the image sensor 284 (see FIGS. 7 and 14). In this regard, the second frame member 280 may serve to support the weight of the yet to be completed camera module instead of the image sensor 288 supporting the weight of the yet to be completed camera module.

As an additional benefit, constructing the dimensions of the second frame member opening 296 may as discussed above facilitate precise alignment of the image sensor 284 over the conductive contacts 248 and central opening 220 and along a lens axis 344 of the lens element 346 of a subsequently attached lens barrel 336 (see FIGS. 14 and 15) so as to receive light focused by the lens element thereon. More specifically, upon appropriate mounting of the second frame member 280 over the second surface 216 and about the central opening 220, the image sensor 284 may be automatically precisely aligned as discussed above upon insertion of the image sensor into the second frame member opening 296.

While not shown, some variations envision that the image sensor 284 may be electrically interconnected to the conductive contacts 248 and then the second frame member 280 may be disposed over the image sensor 284 and mounted to the second surface 216. In any case, use of the flexible tape substrate 200 advantageously allows for a reduction in the thermo-compression bonding force needed during the flip chip process and allows for the use of gang bonding (which can increase camera module throughput). Furthermore, use of the flexible tape substrate 200 allows for use of a thinner image sensor due to a closer match of coefficients of thermal expansion of the tape substrate 200 and the die of the image sensor 184.

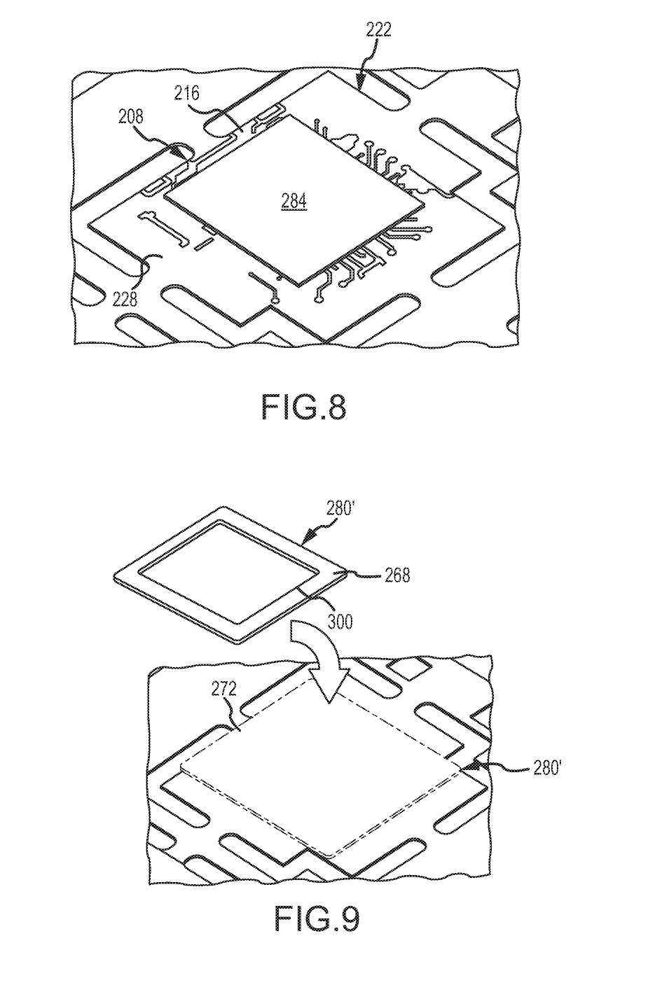

In another arrangement and turning to FIG. 9, a second frame member 280′ may include a cavity 300 that is sized to cover the image sensor 284 and may be made of any appropriate conductive (e.g., thermally) material. In this regard, the second frame member 280′ may function to serve as a heat spreader or heating spreading device for heat generated by image sensor 284 and/or other components of the camera module (e.g., an important factor for maintaining image quality during a video mode of the camera module). With additional reference to FIG. 15 (e.g., a cross-sectional view of a completed camera module 312′ incorporating the second frame member 280′), the cavity 300 may extend from the first surface 288′ towards but short of the second surface 292′ (in contrast to the opening 296 of the second frame member 280 which extends all the way through the second frame member 280 between the first and second surfaces 288, 292). In this regard, the second surface 272 of the second frame member 280′ is generally sized to extend over and cover the central opening 220 of the flexible printed circuit 204. For instance, the image sensor 284 may be appropriately electrically interconnected to the conductive contacts 248 (FIG. 6) on the second surface 216 of the body portion 208 (see FIG. 8), and then the second frame member 280′ may be secured to the second surface 216 in a manner so that the cavity 300 covers and generally conceals the image sensor 284 (see FIG. 9). Thus, the cavity 300 may have dimensions (e.g., thickness, width, length) that are substantially the same as those of the image sensor 284.

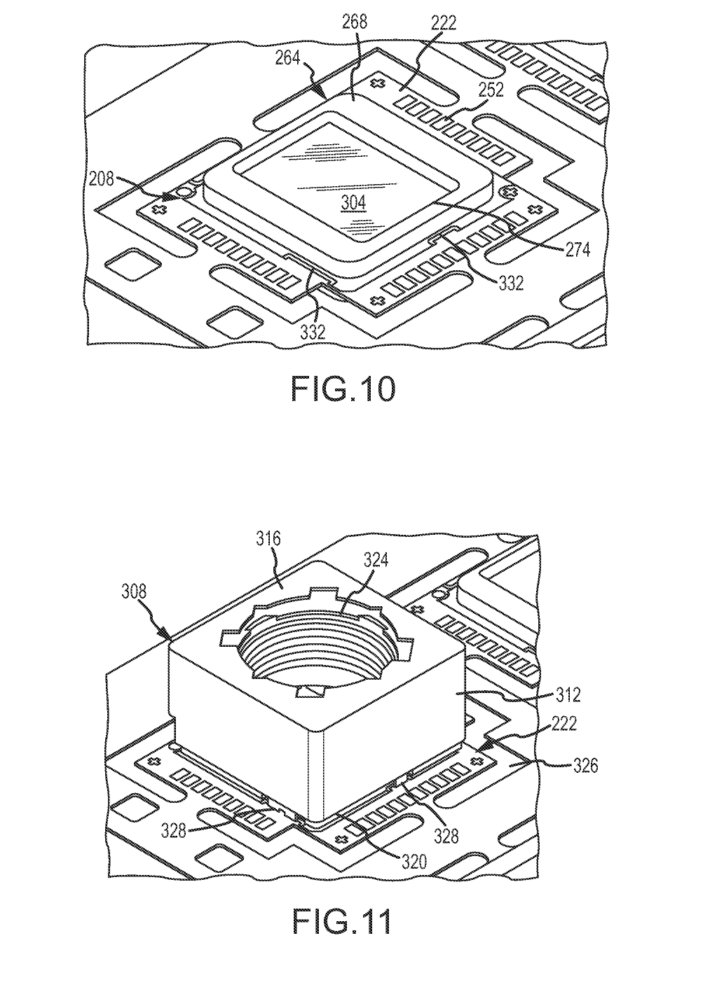

Turning back to FIG. 2, the method 100 may include inserting 120 an infrared (IR) filter 304 (e.g., made of glass) into the first frame member opening 274 over the central opening 220 and appropriately securing the IR filter 304 to the first surface 212 of the body portion 208. See FIG. 10. Similar to the image sensor 284 and second frame member 280, the first frame member opening 274 may have dimensions that are substantially the same as those of the IR filter 304 so that upon appropriate mounting of the first frame member 264 to the first surface 212, insertion of the IR filter 304 into the first frame member opening 274 serves to automatically align the IR filter 304 over the image sensor 284 and along the lens axis 344 of a subsequently attached lens element 340.

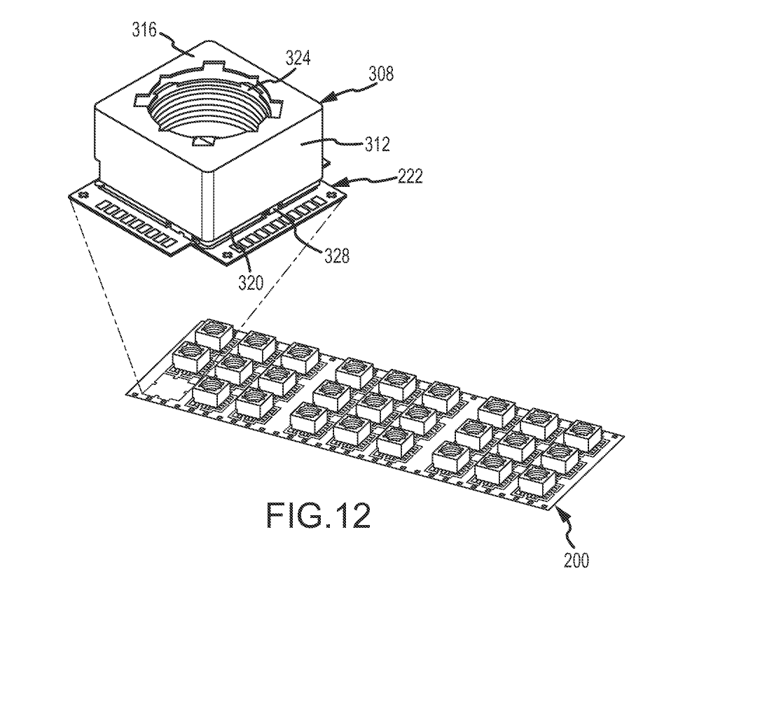

The method 100 may also include mounting 124 a housing 308 over the first frame member 264 to the first surface 212 of the body portion 208. See FIG. 11. For instance, the housing 308 (e.g., constructed of a thermoplastic polymer such as polyvinyl chloride or PVC) may include a tubular body 312 having opposing first and second (e.g., free) ends 316, 320 and an internal cavity (e.g. hollow passageway) 324 extending through the tubular body 312 between the first and second ends 316, 320. As used herein, the “tubular” body 312 may be in the form of a body of any appropriate cross-sectional shape (e.g., oval, circular, square, etc.) and having a hollow passageway (i.e., the internal cavity 324) extending therethrough. In one arrangement, the tubular body 312 may have a constant or non-constant cross-sectional shape between the first and second ends 316, 320. In another arrangement, the second end 320 may include a number of tabs 328 disposed about a perimeter thereof that are adapted to align with a corresponding number of indications 332 (e.g., lines, marks, etc.) disposed on the first surface 212 of the body portion 208 about the central opening 220 (e.g., see FIGS. 3b, 4, 5, 10 and 11). For instance, the tabs 328 and indications 332 may be appropriately formed and sized so that upon alignment of the tabs 328 and indications 332 and subsequent securement between the same (e.g., via adhesives), the internal cavity 324 of the housing 308 may be automatically aligned with the central opening 220, IR filter 304 and image sensor 284 along an axis 344 (e.g., lens axis of a lens element). See FIGS. 14-15. Upon mounting of the housing 308 over the first surface 212 of the body portion 208, the wing members 222 extend away from the housing 308 (see FIGS. 11-12) for reasons that will be discussed below.

Returning to FIG. 2, the method 100 may also include separating 128 the flexible printed circuit 204 from the flexible tape substrate 200 (e.g., along separation features 326 surrounding each flexible printed circuit 204 on or within the flexible tape substrate 200, such as openings, score lines, marks, etc.). See FIGS. 11-12. For instance, use of the flexible tape substrate 200 (i.e., as opposed to a ceramic substrate made up of an increased number of layers, such as eight layers) allows the flexible printed circuit 204 to be punched from the flexible tape substrate 200 (e.g., instead of the snapping or dicing process required to separate a printed circuit from a ceramic substrate).

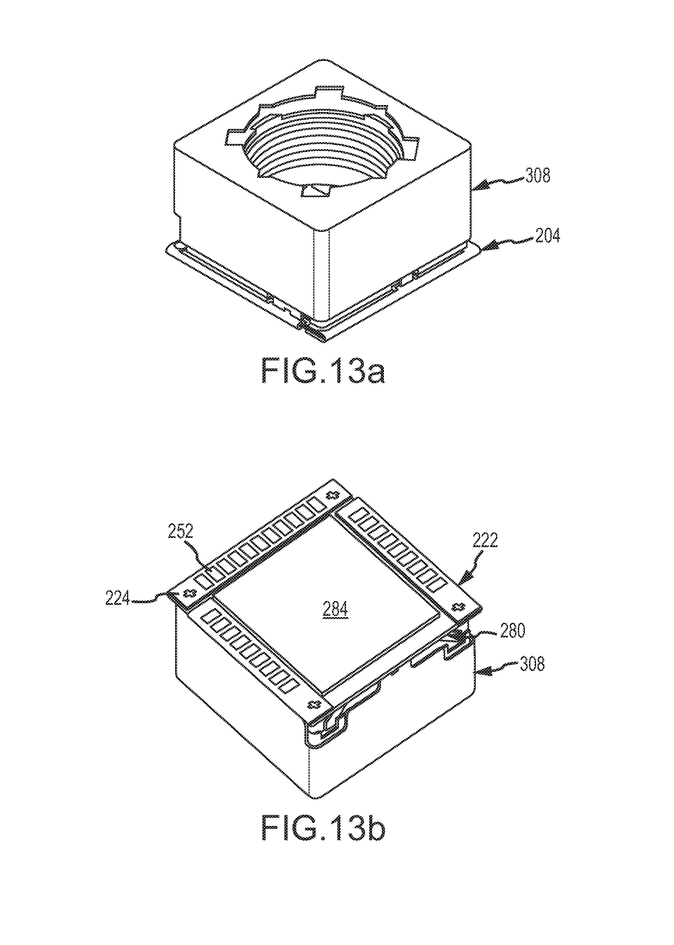

The method 100 also includes folding 132 (e.g., bending, manipulating, deforming) the wing members 122 onto the second frame member 280/280′ and securing the second surface 228 of the wing members 222 to the second frame member 280/280′ (e.g., via pressure sensitive adhesives) so that the conductive contacts 252 of the wing members 222 face away from the body portion 208 and the second frame member 280. Stated differently, the wing members 122 may be folded 132 from a first position whereby the wing members 122 are generally co-planar with the body portion 208 and the conductive contacts 252 of the wing members 122 generally face in the same direction as the conductive contacts 244 of the body portion 208 (e.g., see FIGS. 3b-12) to at least one second position whereby the wing members 122 are free from being co-planar with the body portion 208 (e.g., see FIGS. 13a-15) and the conductive contacts 252 of the wing members 122 generally face in a different direction than the conductive contacts 244 of the body portion 208. In one arrangement, the wing members 122 may be folded and secured to the second surface 292/292′ of the second frame member 280/280′ so that at least a portion of each wing member 122 resides in a plane that is generally parallel to a plane in which the body portion 208 resides (e.g., see FIGS. 14-15) and the conductive contacts 252 of the wing members 122 face in a direction that is spaced about 180° from a direction in which the conductive contacts 244 of the body portion 208 face. In another arrangement (not shown), each wing member 122 may be folded and secured to a lateral surface (not labeled) of the second frame member 280/280′ so that the conductive contacts 252 of the wing members 122 face in a directed that is spaced about 90° from a direction in which the conductive contacts 244 of the body portion 208 face.

As discussed previously, the conductive contacts 252 of the wing members 222 are electrically interconnected to the conductive contacts 244, 248 of the body portion 208 via a number of conductive traces (not shown). As also mentioned above, the surface mount components 260 and the image sensor 284 are appropriately electrically connected to the conductive contacts 244, 248 of the body portion 208. In this regard, the conductive contacts 252 of the wing members 222 advantageously provide an electrical path to the surface mount components 260 and image sensor 284 (i.e., via the conductive traces and conductive contacts 244, 248) in a manner that is free of using vias that extend through the body portion 208 of the flexible printed circuit 204 and the attendant drawbacks and inefficiencies associated with the use of vias. See FIGS. 3b, 6, 14 and 15 (note that the conductive contacts and traces are not shown in FIGS. 14-15 in the interest of clarity).

In any event, the method 100 may include inserting 136 (e.g., threading, pushing and twisting, etc.) a lens barrel 336 having at least one lens element 340 (and a transparent cover 348 disposed within an aperture 352 of the lens barrel 336) into the internal cavity 324 of the housing 308 to form a camera module 312/312′. See FIGS. 14-15. As shown, the lens element 340, IR filter 304, central opening 220 and image sensor 384 may generally be aligned with each other along a common axis 344 (e.g., a lens axis of the lens element 340). For instance, the camera module 312 may be mounted onto any appropriate circuit board or into any appropriate receiving location (e.g., receiving aperture) in a consumer product (e.g., wireless telephones, cell phones, personal digital assistants (PDAs), other handheld electronic devices) that is in communication with a central processor or controller so that the conductive contacts 252 of the wing members 222 are in contact with corresponding conductive contacts of the circuit board or receiving location. Any appropriate anisotropic conductive paste (ACP), other conductive epoxy, and/or the like may be disposed between corresponding conductive contacts to electrically secure the same. While the camera modules 312/312′ have been shown in FIGS. 14-15 as including the lens barrel 336, the disclosure is not so limited. For instance, the camera module 312/312′ could be considered to be the intermediate product shown in FIGS. 13a-13b without the lens barrel 336 disposed within the internal cavity 324 of the housing 308.

The method 100 provides numerous advantages over previous camera module fabrication methods. In one regard, use of the flexible substrate tape 200 instead of the more traditional ceramic substrates allows for a reduction of substrate layers from eight or more down to, for instance, two to four layers. Reducing the number of substrate layers advantageously reduces substrate cost, substrate warpage, substrate thickness, and overall thickness of the camera module 312/312′. For instance, the method 100 allows warpage and thickness of the substrate (e.g., the body portion 208) to be controlled to within +/−15 um with two layers of bonding film as compared to ceramic substrates having eight layers of bonding film within +/−60 um. Furthermore, use of the flexible substrate tape 200 instead of the more traditional ceramic coupon size allows for an increase in the number of camera modules that can be produced per unit time (e.g., an increase in units per hour (UPH) of 30% or more).

Still further, use of the flexible substrate tape 200 allows for a reduction in the thermo-compression bonding force needed during the flip chip process (i.e., because bonding on the tape surface requires less force than does bonding on a ceramic substrate), and allows for use of a thinner image sensor due to a closer match of coefficients of thermal expansion of the tape substrate and the die of the image sensor. Also, use of the flexible substrate tape 200 allows for the use of plated conductive (e.g., gold) bumps instead of stud bumps (e.g., due to the flatness of the tape 200) which may serve to further reduce the thickness of the camera module 312/312′. Moreover, use of the flexible substrate tape 200 allows for the formation of a number of flexible leads or wing members 222 extending out from the body portion 208 of each of the flexible printed circuits 204 that may eliminate or at least reduce the need for a number of vias extending through the body portion 208 for reasons discussed previously.

Use of the first/upper and second/lower frame members 264, 280 in the method 100 also provides a number of advantages. More specifically, use of the upper or first frame member 264 (e.g., molding) advantageously covers and conceals the surface mount components 260 to reduce contamination and protect the surface mount components 260 from heat generated by the image sensor bonding process (e.g., thermo-compression) and thereby increase reliability of the components 260. The upper frame member 264 may also provide for automatic alignment of the IR filter 304, tubular housing 308 and lens barrel 336 over the image sensor 284. Furthermore, use of the lower frame member 280/280′ may advantageously serve to center and/or align the image sensor 284 over the central opening 220 and along the lens axis 344 of a lens element 340, dissipate heat generated by the image sensor 284, enhance the structural integrity of the camera module 312/312′, protect the image sensor 284 from external forces, and the like.

Many deviations may be made from the specific embodiments disclosed in the specification without departing from the spirit and scope of the invention. As just one example, some arrangements envision that the step of inserting 120 the IR filter 304 into the first frame member opening 274 before the step of attaching 116 the second frame member 280 and image sensor 284 to the second surface 216 of the body portion 208. Other arrangements are also envisioned and encompassed within the scope of the present disclosure. Any of the embodiments, arrangements, or the like discussed herein may be used (either alone or in combination with other embodiments, arrangement, or the like) with any of the disclosed aspects. Merely introducing a feature in accordance with commonly accepted antecedent basis practice does not limit the corresponding feature to the singular. Moreover, any failure to use phrases such as “at least one” also does not limit the corresponding feature to the singular. Use of the phrase “at least generally,” “at least partially,” “substantially” or the like in relation to a particular feature encompasses the corresponding characteristic and insubstantial variations thereof. For example, a component that is “substantially equal” to another component covers both an insubstantial variation of the components being equal in addition to the components being equal. Finally, a reference of a feature in conjunction with the phrase “in one embodiment” does not limit the use of the feature to a single embodiment.

While the invention has been illustrated and described in detail in the drawings and foregoing description, such illustration and description is to be considered as exemplary and not restrictive in character. For example, certain embodiments described hereinabove may be combinable with other described embodiments and/or arranged in other ways (e.g., process elements may be performed in other sequences). Accordingly, it should be understood that only the preferred embodiment and variants thereof have been shown and described and that all changes and modifications that come within the spirit of the invention are desired to be protected.

What is claimed is:

1. A method for use in building a camera module for use in electronic devices, comprising:
providing a flexible printed circuit tape portion comprising a body portion having opposing first and second surfaces and a plurality of conductive contacts disposed on the first and second surfaces, a central opening disposed through the body portion, and at least one wing member extending from the body portion and including a plurality of conductive contacts, wherein the conductive contacts of the body portion are electrically interconnected to the conductive contacts of the at least one wing member;
mounting a frame member to the second surface of the body portion about the central opening;
electrically interconnecting an image sensor to the conductive contacts on the second surface of the body portion and over the central opening; and
folding the at least one wing member onto the frame member so that the conductive contacts of the wing member generally face in a direction that is different from a direction in which the conductive contacts on the first surface of the body portion face.

2. A method as set forth in claim 1, wherein after the folding, the conductive contacts of the at least one wing member generally face in a direction that is spaced by about 180° from the direction in which the conductive contacts on the first surface of the body portion face.

3. A method as set forth in claim 1, wherein after the folding, at least a portion of the at least one wing member resides in a plane that is generally parallel to a plane in which the body portion resides.

4. A method as set forth in claim 1, further including:
securing the at least one wing member to the frame member.

5. A method as set forth in claim 1, wherein the at least one wing member includes a first wing member, wherein the flexible printed circuit tape portion further includes a second wing member spaced from the first wing member, and wherein the method further includes:
folding the second wing member onto the frame member so that the conductive contacts of the second wing member generally face in a direction that is different from the direction in which the conductive contacts on the first surface of the body portion face.

6. A method as set forth in claim 5, wherein the flexible printed circuit tape portion further includes a third wing member disposed between the first and second wing members, and wherein the method further includes:
folding the third wing member onto the frame member so that the conductive contacts of the third wing member generally face in a direction that is different from the direction in which the conductive contacts on the first surface of the body portion face.

7. A method as set forth in claim 1, further including:
electrically mounting a plurality of surface mount components to the conductive contacts on the first surface of the body portion.

8. A method as set forth in claim 7, wherein the frame member mounted to the second surface of the body portion comprises a second frame member, and wherein the method further includes
mounting a first frame member to the first surface of the body portion and over the surface mount components.

9. A method as set forth in claim 8, wherein the first frame member includes opposing first and second surfaces and an opening extending between the first and second surfaces, and wherein the method further includes:
inserting an infrared (IR) filter into the first frame member opening; and
securing the IR filter to the first surface of the body portion.

10. A method as set forth in claim 8, further including:
mounting a housing to the first surface of the body portion, wherein the housing comprises a tubular body having opposing first and second ends and an internal cavity between the first and second ends, and wherein the internal cavity is generally aligned with the central opening.

11. A method as set forth in claim 10, wherein the folding occurs after the first frame member and housing are mounted to the body portion.

12. A method as set forth in claim 10, further including:
inserting a lens barrel including at least one lens element into the internal cavity.

13. A method as set forth in claim 1, wherein the flexible printed circuit tape portion is provided on a length of flexible tape substrate along with a plurality of other flexible printed circuit tape portions, wherein the method further includes:
separating the flexible printed circuit tape portion from the length of flexible tape substrate.

14. A method as set forth in claim 13, wherein the separating includes punching.

15. A method as set forth in claim 1, image sensor is electrically interconnected to the body portion before the frame member is mounted to the body portion.

16. A method as set forth in claim 15, wherein the frame member includes opposing first and second surfaces and a cavity extending from one of the first and second surfaces towards but short of the other of the first and second surfaces, and wherein the mounting includes:
mounting the cavity over the image sensor.

17. A method as set forth in claim 1, wherein the image sensor is electrically interconnected to the body portion after the frame member is mounted to the body portion.

18. A method as set forth in claim 17, wherein the frame member includes opposing first and second surfaces and an opening extending between the first and second surfaces, and wherein the electrically interconnecting the image sensor includes:
inserting the image sensor into the frame member opening.

19. A method as set forth in claim 1, wherein the electrically interconnecting the image sensor includes:
performing a flip chip bonding process between the image sensor and the conductive contacts of the body portion.

20. An apparatus, comprising:
a flexible tape substrate comprising a body portion having opposing first and second surfaces and a plurality of conductive contacts disposed on the first and second surfaces, a central opening disposed through the body portion, and at least one wing member extending from the body portion and including a plurality of conductive contacts, wherein the conductive contacts of the body portion are electrically interconnected to the conductive contacts of the at least one wing member;
a frame member mounted to the second surface of the body portion about the central opening; and
an image sensor electrically interconnected to the conductive contacts on the second surface of the body portion and over the central opening, wherein the at least one wing member is secured to the frame member so that the conductive contacts of the at least one wing member generally face in a direction that is different from a direction in which the conductive contacts on the first surface of the body portion face.

21. An apparatus as set forth in claim 20, wherein the frame member includes a first surface secured to the second surface of the body portion, an opposing second surface, and an opening extending between the first and second surfaces, and wherein the image sensor is disposed within the frame member opening.

22. An apparatus as set forth in claim 21, wherein the frame member includes a thickness extending from the first surface to the second surface, wherein the image sensor comprises a thickness extending from a first surface of the image sensor to a second surface of the image sensor, and wherein the frame member thickness is substantially equal to or greater than the image sensor thickness.

23. An apparatus as set forth in claim 21, wherein the frame member opening extends from the first surface of the frame member towards but short of the second surface of the frame member.

24. An apparatus as set forth in claim 23, wherein the frame member includes a thermally conductive material.

25. An apparatus as set forth in claim 20, wherein the frame member includes a second frame member, and wherein the apparatus further includes:
a plurality of surface mount components electrically interconnected to the conductive contacts on the first surface of the body portion; and
a first frame member mounted to the first surface of the body portion and over the surface mount components.

26. An apparatus as set forth in claim 25, wherein the first frame member includes opposing first and second surfaces and an opening extending between the first and second surfaces, and wherein the apparatus further includes:
an infrared (IR) filter disposed within the first frame member opening and secured to the first surface of the body portion.

27. An apparatus as set forth in claim 25, further including:
a housing mounted to the first surface of the body portion and over the first frame member, wherein the housing comprises a tubular body having opposing first and second ends and an internal cavity between the first and second ends, and wherein the internal cavity is generally aligned with the central opening.

28. An apparatus as set forth in claim 27, further including:
a lens barrel including at least one lens element disposed within the internal cavity.

29. An apparatus as set forth in claim 25, wherein the first frame member includes a polymer.

30. An apparatus as set forth in claim 20, wherein the at least one wing member includes a first wing member, wherein the flexible tape substrate further includes a second wing member spaced from the first wing member, and wherein the second wing member is secured to the frame member so that the conductive contacts of the second wing member generally face in a direction that is different from the direction in which the conductive contacts on the first surface of the body portion face.

31. An apparatus as set forth in claim 30, wherein the flexible tape substrate further includes a third wing member disposed between the first and second wing members, and wherein the third wing member is secured to the frame member so that the conductive contacts of the third wing member generally face in a direction that is different from the direction in which the conductive contacts on the first surface of the body portion face.
